(19) United States
(12) Patent Application Publication
(10) Pub. No.: US 2026/0043760 A1
(43) Pub. Date: Feb. 12, 2026

(54) RESERVOIR POROSITY PREDICTION TOOL AND USES THEREOF

(71) Applicant: SAUDI ARABIAN OIL COMPANY, Dhahran (SA)

(72) Inventors: Jun GAO, Dhahran (SA); Xupeng HE, Dhahran (SA); Hyung KWAK, Dhahran (SA)

(73) Assignee: SAUDI ARABIAN OIL COMPANY, Dhahran (SA)

(21) Appl. No.: 18/799,723

(22) Filed: Aug. 9, 2024

(51) Int. Cl. G01N 24/08

(52) U.S. Cl. CPC G01N 24/081

(57) ABSTRACT

Systems and methods are disclosed relating to reservoir permeability prediction. Relaxation times (T2) spatial maps for core sample segments can be generated. Capillary pressures at an inlet of the core sample segments can be computed and T2 time cutoffs for the core sample segments can be computed based on the T2 spatial maps and the capillary pressures. Candidate T2 time cutoffs can be identified from the computed T2 time cutoffs. Data points can be generated based on the identified candidate T2 time cutoffs and the computed capillary pressures. Each data point of the data points can include a capillary pressure value and a candidate T2 time cutoff value. The data points can be processed using a clustering algorithm to group the data points into data clusters, and a permeability of the reservoir can be predicted based on the data clusters.

### FIELD OF THE DISCLOSURE

This disclosure relates generally to reservoir characterization, and more specifically, to a tool for calculating reservoir (or rock formation) porosity.

### BACKGROUND OF THE DISCLOSURE

Carbonate reservoir rocks are geological formations composed primarily of carbonate minerals such as calcite, aragonite, and dolomite. Carbonate reservoirs are significant sources of hydrocarbons, containing oil and gas trapped within pore spaces and fractures.

### SUMMARY OF THE DISCLOSURE

Various details of the present disclosure are hereinafter summarized to provide a basic understanding. This summary is not an extensive overview of the disclosure and is neither intended to identify certain elements of the disclosure nor to delineate the scope thereof. Rather, the primary purpose of this summary is to present some concepts of the disclosure in a simplified form prior to the more detailed description that is presented hereinafter.

According to an embodiment, a method can include generating relaxation times (T2) spatial maps for core sample segments of a core sample from a reservoir, computing capillary pressures at an inlet of the core sample segments, computing T2 time cutoffs for the core sample segments based on the T2 spatial maps and the computed capillary pressures, identifying candidate T2 time cutoffs from the computed T2 time cutoffs, generating data points based on the identified candidate T2 time cutoffs and the computed capillary pressures, each data point of the data points can include a capillary pressure value and a candidate T2 time cutoff value, processing the data points using a clustering algorithm to group the data points into data clusters, and predicting a permeability of the reservoir based on the data clusters.

According to another embodiment, a system can include a tool that can include a nuclear magnetic resonance (NMR) calculator to generate T2 spatial maps for core sample segments based on T2 times computed for one or more core sample segments of a core sample from a reservoir, a pressure calculator to compute capillary pressures at an inlet of the core sample segments, a T2 time cutoff calculator to: compute T2 time cutoffs for the core sample segments based on the T2 spatial maps and the computed capillary pressures and identify candidate T2 time cutoffs from the computed T2 time cutoffs and generate data points based on the identified candidate T2 time cutoffs and the computed capillary pressures, each data point of the data points comprising a capillary pressure value and a candidate T2 time cutoff value. The tool can further include a clustering algorithm to process the data points to group the data points into data clusters, and a permeability calculator to predict a permeability of the reservoir based on the data clusters.

In yet another embodiment, a method can include providing a reservoir model based on a predicted permeability of a reservoir. The predicted permeability can be generated based on data clusters provided by a clustering algorithm based on data points. Each data point of the data points can include a capillary pressure value and a candidate T2 time cutoff value for one or more core sample segments of a core sample from the reservoir. The method can further include simulating the reservoir model to predict fluid flow in the reservoir, and optimizing a hydrocarbon recovery process of hydrocarbons from the reservoir based on one or more predictions from the simulation of the reservoir model.

Any combinations of the various embodiments and implementations disclosed herein can be used in a further embodiment, consistent with the disclosure. These and other aspects and features can be appreciated from the following description of certain embodiments presented herein in accordance with the disclosure and the accompanying drawings and claims.

### BRIEF DESCRIPTION OF THE DRAWINGS

FIG. 1 is an example of a system with a tool for predicting a permeability of a rock formation (or reservoir).

FIG. 2 is an example of a transverse relaxation (T2) spatial map.

FIG. 3 is an example of saturation saturation profiles.

FIG. 4 is an example of a core sample segment at an inlet.

FIG. 5 is an example of a T2 capillary pressure curve for a core sample segment.

FIG. 6 is an example of T2 capillary pressure curves for core sample segments.

FIG. 7 is an example of a system for hydrocarbon recovery optimization and recovery management.

FIG. 8 is an example of a method for generating saturation profiles.

FIG. 9 is an example of a method for predicting a permeability of a rock formation.

FIG. 10 is an example of a method for hydrocarbon recovery optimization.

FIG. 11 is a block diagram of a system that can be used to perform one or more methods according to an aspect of the present disclosure.

FIG. 12 is an example of a cloud computing environment that can be used to perform one or more methods according to an aspect of the present disclosure.

### DETAILED DESCRIPTION

Embodiments of the present disclosure will now be described in detail with reference to the accompanying Figures. Like elements in the various figures may be denoted by like reference numerals for consistency. Further, in the following detailed description of embodiments of the present disclosure, numerous specific details are set forth in order to provide a more thorough understanding of the claimed subject matter. However, it will be apparent to one of ordinary skill in the art that the embodiments disclosed herein may be practiced without these specific details. In other instances, well-known features have not been described in detail to avoid unnecessarily complicating the description. Additionally, it will be apparent to one of ordinary skill in the art that the scale of the elements presented in the accompanying Figures may vary without departing from the scope of the present disclosure.

Examples are disclosed herein relating to rock formation permeability prediction. A formation is a geological unit or layer of rock of a reservoir. Formations are generally referred to as rock formations. Rock formations can be studied for hydrocarbon potential and other geological properties, such as by using nuclear magnetic resonance (NMR) well logging. To determine geological properties of a rock formation, such as porosity, permeability and/or fluid content, a core sample of the rock formation is procured and provided to a laboratory. The core sample is a cylindrical section that has been extracted from a borehole in the rock formation. Porosity refers to a volume percentage of void space (pores) in the rock formation. Permeability is a measure of how fluids flow through the rock formation.

For example, to determine the geological properties of the rock formation the laboratory saturates the core sample with a fluid (e.g., water or brine) by immersing the core sample in the fluid under pressure until no further fluid is absorbed by the core sample. Then, the core sample is placed inside an NMR instrument (or device), such as a laboratory-scale NMR spectrometer. The NMR instrument applies a magnetic field to the core sample, which causes the nuclear spins of protons in the fluid within the pores (or pore spaces) of the core sample to align with the magnetic field. The NMR instrument emits radiofrequency (RF) pulses at the core sample to excite aligned nuclear spin protons, causing these protons to absorb energy and change a spin state. After RF pulsing, the protons release the absorbed energy, returning to an original spin state, while emitting signals (referred to as NMR signals), which can be detected by the NMR instrument. The NMR instrument records the emitted (NMR) signals over time to capture a decay of the emitted signals to provide NMR data. The NMR data can be processed to determine a relaxation time for each NMR signal in the NMR data. The relaxation time can include a transverse relaxation time, known as T2. T2 is a time constant that represents a decay of a transverse component of nuclear magnetization. The transverse relaxation time characterizes how quickly a coherence of spins in a transverse plane is lost, resulting in a decay of transverse magnetization. This decay process affects the NMR signal, as a strength of the NMR signal decreases over time due to a loss of coherence among the spins. Thus, the rate at which the NMR signal decays is characterized by the transverse relaxation time (T2).

In the core sample, pore spaces can vary in size and impact the transverse relaxation time. Larger pores can have longer transverse relaxation times. By contrast, smaller pores can have shorter transverse relaxation times because protons in smaller pores experience faster molecular motion and interactions, leading to shorter T2 times. Thus, transverse relaxation times reflect a pore size distribution of pore sizes in the core sample. To quantify the porosity of the core sample (and thereby the rock formation), the laboratory processes the NMR data to determine the T2 times and uses the determined T2 times to predict the porosity of the core sample.

For example, to predict the porosity based on the NMR data, the NMR data is analyzed to determine the T2 times for the core sample. This can be done by fitting mathematical models, such as exponential decay curves to the NMR signals represented by the NMR data. A curve fitting algorithm can be used to determine the T2 times and corresponding amplitudes, which represent contributions from different pore sizes in the core sample to provide a T2 time (T2) spectrum. The T2 time spectrum can include one or more T2 times and corresponding amplitudes (or intensities) for the core sample. The T2 time spectrum can be plotted to show an amplitude or intensity of NMR signal decay as a function of relaxation time. In some examples, to estimate the porosity of the core sample, an area under the T2 time spectrum can be integrated to determine a total pore volume of the core sample. By integrating the area under the T2 time spectrum, the amplitudes or intensities of relaxation signals associated with different pore sizes can be summed. This total integrated amplitude is proportional to a pore volume of pore space within the core sample. The porosity of the rock core can be calculated based on a ratio of pore volume of the rock sample to a total pore volume. The total pore volume can be determined from physical dimensions of the core sample.

Once the porosity has been estimated (or determined), the permeability of the core sample can be predicted. To predict the permeability, a permeability prediction model, such as a Timur-Coats expression can be used:

$$k = {( \frac{ϕ}{C} )}^{m} {( \frac{FFI}{BVI} )}^{n} , \qquad ( 1 )$$

wherein BVI is bulk volume irreducible, FFI is free fluid index, ϕ is porosity, k is permeability, and C, m, and n are the fitting parameters.

Laboratories use default fitting parameter values, such as 4 for m and 2 for n, in some instances these parameters are adjusted. To predict permeability accurately, the fitting parameter C has to be determined, for which the laboratory uses a calibration method to determine. The fitting parameter C represents a scaling factor or calibration constant that controls a relationship between porosity (ϕ) and permeability (k) in expression (1). The fitting parameter C influences how changes in a porosity translate to changes in a permeability. By adjusting the value of the fitting parameter C, the permeability prediction model can be tuned to better reflect specific geological characteristics of the rock formation under analysis. Accordingly, an accuracy of the permeability prediction model is influenced by the fitting parameter C.

To determine the fitting parameter C, the calibration method begins with conducting two NMR measurements on respective core samples of the rock formation, which can be referred to as a first core sample and a second core sample, respectively. The first core sample is saturated at 100% water saturation, for example, by immersion or vacuum saturation so that all pore spaces are filled with a liquid, such as a water. The second core sample is desaturated to an irreducible water saturation level, representing a minimum amount of water that is to remain in pore spaces. The irreducible water saturation level can be achieved through centrifuge desaturation. For example, the second core sample can be placed in a centrifuge and spun at a specified rotation speed for a predetermined duration to remove excess water from the pore spaces of the second core sample. A centrifugal force is generated by the rotation and causes the water to be expelled from pores of the second core sample.

Then, T2 time spectrums can be obtained from NMR measurements (NMR data) conducted at 100% water saturation and irreducible water saturation. After obtaining T2 time spectrums for each of the first and second core samples, which can be referred to as first and second T2 time spectrums, respectively, a T2 time cutoff value can be determined (or defined). The T2 time cutoff value represents a maximum T2 time beyond which no significant signal is detected in a T2 time spectrum.

For example, NMR measurements are conducted on the first core sample when it is saturated with water (100% water saturation). From the NMR measurements for the first core sample, parameters such as porosity and the first T2 spectrum are obtained. The first T2 spectrum from the water saturated sample is used to calculate a first FFI and a first BVI using a first T2 time cutoff value. NMR measurements are then conducted on the second core sample after desaturation to an irreducible water saturation level. Parameters such as the porosity and the transverse relaxation time spectrum are obtained from the NMR measurements for the second core sample. The T2 time spectrum for the second core sample is then used to calculate a second FFI and a second BVI using a second T2 time cutoff value. Then, first and second fitting parameters C can be calculated based on corresponding first and second BVI and FFI values. The first and second fitting parameters C can be averaged, and the averaged fitting parameter C can be used in equation (1) for estimating permeability. In some examples, an average T2 time cutoff value can also be determined by averaging the first and second T2 time cutoff values for the first and second core samples. Once the average T2 time cutoff value is determined, this value can be used to calculate FFI and BVI values for the core sample. The calculated FFI and BVI values and the averaged fitting parameter C can be used for the core sample to predict permeability using equation (1) for the core sample (thereby the rock formation).

During the calibration method, maintain proper desaturation pressure for desaturation of the second core sample is challenging and influences (or controls) an amount of irreducible water saturation that is achieved, that is, an amount of water that remains in the pore spaces of the second core sample (the rock) after desaturation. Different desaturation pressures, such as 50, 100, or 200 PSI can be used depending on a type of core sample under analysis. For example, for high permeability sandstone samples or reservoirs (e.g., (approximately larger than tens of millidarcy)), lower pressures (e.g., 50 or 100 PSI) can be sufficient to achieve irreducible water saturation. However, for heterogeneous carbonate or low permeability reservoirs, higher pressures are needed, and even then, achieving irreducible water saturation may be difficult to achieve. Heterogencity refers to variation in properties such as porosity, permeability, and/or lithology within a reservoir.

Carbonate reservoirs exhibit complex pore structures, and this complexity results in significant variations in fluid flow behavior and fluid distribution within the reservoir (the core sample), leading to challenges in reservoir characterization and prediction. Thus, in heterogeneous carbonate reservoirs variations in pore structure and/or fluid distribution makes it difficult to completely remove water from all pore spaces, even at high desaturation pressures. The uncertainty in achieving irreducible water saturation can lead to discrepancies between measured and predicted reservoir properties, such as permeability. When irreducible water saturation is uncertain or difficult to achieve, it can impact a correlation between measured parameters (such as NMR-derived FFI and BVI) and actual reservoir properties. Permeability prediction models, such as the Timur-Coates equation (1), need accurate measurements of parameters, such as porosity, irreducible water saturation so that accurate permeability predictions can be made. Thus, if there is low correlation between measured parameters and actual reservoir properties because of difficulties in achieving irreducible water saturation this can lead to inaccuracies and uncertainty in permeability predictions. Moreover, in heterogeneous carbonate reservoirs, where variations in pore structure and fluid distribution are common, the challenges in achieving accurate irreducible water saturation can exacerbate uncertainties in permeability prediction.

Furthermore, uncertainty in permeability predictions (that is a permeability accuracy) is also impacted by existing laboratory desaturation experiments. For example, an effectiveness of the desaturation process using centrifuge desaturation depends on factors, such as centrifuge speed, duration of centrifugation, and core sample properties. The effectiveness of centrifuge desaturation can be influenced by a length of the core sample and a rotation speed of the centrifuge. When the rotation speed of the centrifuge is fixed, shorter core samples experience less centrifugal force compared to longer core samples during centrifugation. This difference in centrifugal force can affect the desaturation efficiency, particularly if the core lengths vary within a group of samples. Thus, if core lengths vary within a group of core samples and the core samples are spun at a same speed in the centrifuge, a desaturation efficiency can differ between core samples. Samples with shorter lengths can retain more fluids in their pore spaces compared to longer core samples. This inconsistency in desaturation efficiency can also contribute to uncertainty in the desaturation process and the accuracy of measured parameters such as irreducible water saturation and permeability.

Examples herein disclose a method and tool for accurate permeability prediction. Using the method herein for permeability prediction overcomes the challenges encountered in laboratory techniques for NMR-based permeability prediction. The method addresses the difficulty in achieving accurate irreducible water saturation, such as in heterogeneous carbonate or low permeability reservoirs, which often leads to uncertainties in measured parameters and subsequent permeability predictions. Furthermore, by using the method of the present disclosure mitigates inconsistencies in desaturation efficiency and inaccuracies in measured parameters, such as irreducible water saturation and permeability. Moreover, the method herein reduces or eliminates complexities posed by heterogeneity in carbonate reservoirs, which complicate fluid flow behavior and distribution, even at high desaturation pressures. Using the method of the present disclosure enhances or improves a correlation between measured parameters and actual reservoir properties, and increases reliability of permeability predictions, for example, when utilizing models like the Timur-Coates expression.

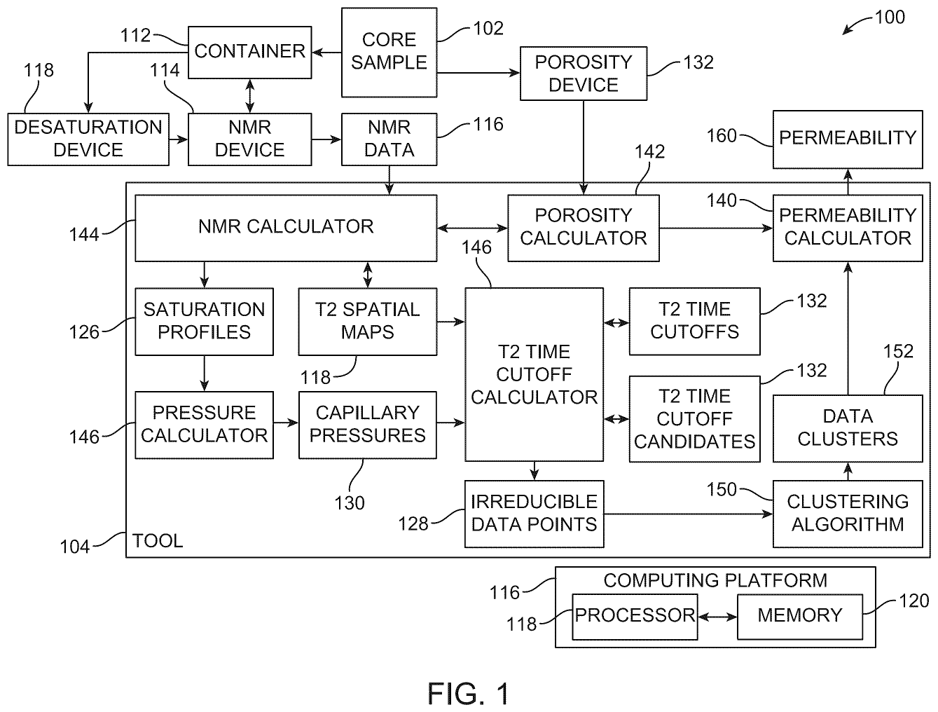

FIG. 1 is an example of a system 100 with a tool 104 for predicting a permeability of a rock formation (or reservoir). For example, one or more components of the system 100 can be used for implementing a rock formation permeability prediction method so that data for determining the one or more fitting parameters of a permeability prediction model can be gathered.

In some examples, the method can begin with one or more core samples 102 of the rock formation being received. The one or more core samples 102 (referred to herein as a core sample) can have similar or different core lengths. The core sample 102 can be dried and cleaned for porosity determination. In some examples, the porosity of the core samples 102 (in its dry and/or clean state) can be measured. In some examples, the core sample 102 is placed in a porosity device 132 and pressured with a gas. In some examples, the porosity device 132 is a Helium porosimeter. Gas can be introduced into a chamber containing a placed core sample. In some examples, Helium is used because its small atomic size allows it to penetrate pores effectively. The amount of gas displaced by the placed core sample is measured. The tool 104 can include a porosity calculator 142. The porosity calculator 142 can calculate a porosity of the core sample 102 based on a pore volume (e.g., the volume of gas displaced by the placed core sample), and a total volume of the placed core sample). For example, to measure the volume of gas needed to saturate the core sample 102, an initial volume of the core sample 102 can be measured, for example, by measuring dimensions (e.g., length, width, and height) of the core sample, which can be provided to the porosity calculator 142. Gas can be gradually introduced into the permeability device 108 to displace any air and/or other fluids present in pore spaces of the placed core sample. As gas fills the pore spaces of the placed core sample, a volume of gas needed to saturate the placed core sample can be measured. This measurement can be obtained by measuring a volume of gas introduced into the permeability device 108. Once the volume of gas that is needed to saturate the placed core sample is determined, the porosity of the placed core sample can be calculated by the porosity calculator 142. The porosity can be calculated by the porosity calculator 142 based on a volume of pore space (volume of gas introduced) and a total volume of the placed core sample. In other examples, the porosity of the core sample 102 can be determined according to a different technique and/or using different types of devices (and/or data).

In some examples, during the method, the core sample 102 can be placed in a container 112 (or chamber) that can hold a saturation liquid, such as Brine. In some examples, the Brine is referred to as a formation brine. The term “formation brine” indicates that the Brine that is being used is representative of a natural saline solution found in reservoir rock formations. The core sample 102 in the container 112 can be saturated with Brine (natural saline solution) to provide a saturated core, and can be labeled or identified as having 100% water saturation.

During the method, in some instances, the saturated core sample is segmented into core sample segments (or saturated core sample segments), and provided to an NMR device 114, such as a laboratory-scale NMR spectrometer can be used. The NMR device 114 can be used to perform NMR measurements (e.g., detect NMR signals) to obtain NMR data 116 for each core sample segment, which can be used by an NMR calculator 144 of the tool 104 to determine one or more T2 times for the core sample segments. The detected NMR signals (characterized by the NMR data 116) can be analyzed by the NMR calculator 144 to compute T2 times (decay rates) of the NMR signals to generate T2 spatial maps 118 (or T2 time spectrums) at full fluid saturation (e.g., 100% water saturation). An amplitude of an NMR signal can be an indication of a total fluid present while a T2 time for the NMR signal provides an indication about a physical environment of the core sample segment (e.g., size of pores within the core sample 102).

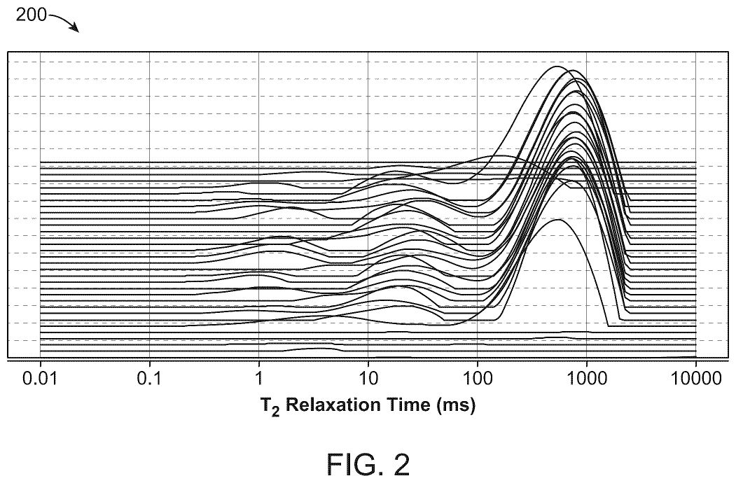

FIG. 2 is an example of a T2 spatial map 200 at full fluid saturation, which can correspond to one of the T2 spatial maps 118, as shown in FIG. 1. Thus, reference can be made to one or more examples of FIG. 1 in the example of FIG. 2. An x-axis of the T2 spatial map 200 can represent T2 times while an y-axis of the T2 spatial map 200 can represent NMR signal amplitude or intensity. The T2 spatial map 200 includes T2 times for different NMR signals captured for a respective spatial region of the core sample 102. Each T2 time of the T2 times 202-230 can represent how quickly (e.g., a rate at which) protons in water molecules within the pores of the core sample 102 lose a transverse magnetization after being perturbed by a magnetic field pulse established by the NMR device 114. Continuing with the example of FIG. 1, in some instances, the NMR signals of the NMR data 116 are known as composite NMR signals, and the NMR calculator 144 can be decomposed the composite NMR signals into its separate component parts to provide a T2 spatial map. A T2 spatial map can characterize a distribution of pore sizes in a core sample. Thus, the T2 spatial map can be representative of pore size distribution, such as in a core sample segment.

For example, the saturated core sample can be divided into discrete segments along its length to provide core sample segments (also can be known as saturated core sample segments). The core sample segments can be uniform or variable in length depending on an NMR resolution. In some examples, the saturated core sample is divided into discrete segments and the discrete segments are saturated to provide the core sample segments. The core sample segments can be used to generate saturation profiles 126. For example, each of the core sample segments at full fluid saturation can be analyzed by the NMR device 114 to provide corresponding NMR data, which can be used by the NMR calculator 144 to obtain T2 time distributions (corresponding to the T2 spatial maps 118). The T2 time distributions can provide information on a total porosity and fluid distribution within the core sample segments at full fluid saturation. For each core sample segment, the NMR calculator 144 can invoke or use the porosity calculator 142 to calculate a porosity for that core sample segment, which can be referred to as an incremental porosity. For each core sample segment, the porosity calculator 142 can determine the incremental porosity based on a pore volume occupied by a fluid and a total volume for a core sample segment. The pore volume for the sample segment can be computed by the porosity calculator 142 based on a T2 spatial map of the T2 spatial maps 118 for the core sample segment. The total volume of the core sample segment can be determined based on dimensions of the core sample segment, for example, a length and diameter. The NMR calculator 144 using computed incremental porosity values and length values determined for the core sample segments full fluid saturation can be used to provide a saturation profile.

After computing the saturation profile for the core sample segments at full fluid saturation, each of the core sample segments can be desaturated partially by a desaturation device 118, which can be implemented in some instances as a centrifuge. The desaturation device 118 can be configured to desaturate the core sample segments at different centrifuge speeds (and thus desaturate incrementally over time) the core sample segments to capture saturation profiles 126 for the core sample segments. For example, each of the core sample segments can be placed into the desaturation device 118 to partially desaturate the core sample segments at a given centrifuge speed. Thus, the desaturation device 120 can be used to create varying fluid saturation levels along different lengths of the saturated core sample. The centrifuge force can drive out the fluid within each core sample segment at different strengths. Following each partial desaturation at a given centrifuge speed of the core sample segment, an NMR measurement using the NMR device 114 can be performed to generate NMR data for each of the core sample segments. In some examples, the NMR device 114 can use a 1D magnetic gradient to perform spatially resolved measurements along a core length of the core sample 102 to provide a T2 time distribution for each segment of the core sample 102 at the given centrifuge speed, which reflects an amount of fluid content in each core sample segment following a round of centrifugal desaturation. A 1D magnetic gradient refers to an application of a magnetic field that varies in strength along a single direction within the NMR device 114 with respect to the core sample segment. The NMR device 114 can establish a gradient that creates a magnetic field that changes gradually or in steps along a single axis. After each partial desaturation of the core sample segments, the NMR device 114 can be used to provide corresponding NMR data, which can be processed by the NMR device 114 to determine T2 spatial maps for the core sample segments at a reduced fluid saturation (e.g., less than 100% liquid saturation). The NMR device 114 can determine the T2 spatial maps for the core sample segments having reduced fluid saturation in a same or similar manner as disclosed herein, such as at full fluid saturation. The NMR device 114 can generate one or more saturation profiles for the core sample segments having a reduced fluid saturation.

Accordingly, a number of partial desaturations can be implemented of the core sample segments to provide a series of saturation profiles, which can be provided as part of the saturation profiles 126. Each saturation profile of the saturation profiles 126 characterizes incrementally a porosity of the core sample segments across a range of saturation levels. The series of saturation profiles obtained from fully saturated to various reduced saturation levels can be compiled into a comprehensive set of saturation profiles corresponding to the saturation profiles 126. In some examples, the saturation profiles 126 can be used by the pressure calculator 146 to calculate capillary pressures 130, as shown in FIG. 1. The saturation profiles 126 can be used by the T2 time cutoff calculator 146 to obtain T2 time cutoffs 132. Thus, the tool 100 can be used to obtain a mapping of capillary pressures 130 versus T2 time cutoffs 132.

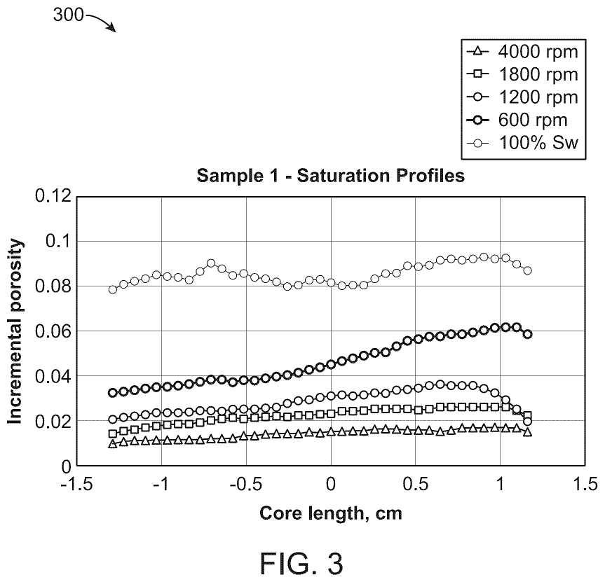

FIG. 3 is an example of a saturation graph 300 of saturation profiles that can be provided as (or part) of the saturation profiles 126, as shown in FIG. 1. Thus, reference can be made to one or more examples of FIGS. 1-2 in the example of FIG. 3. In some examples, the saturation profiles can be referred to as a ID saturation profile. An x-axis of the saturation graph 300 can represent a depth (e.g., a core length) in centimeters (cm) of a core sample and thus to one or more core sample segments. A y-axis of the saturation graph 300 can represent a porosity of the one or more core sample segments at different fluid saturation levels (e.g., water saturation levels).

In some examples, during the method, a desaturation process can be implemented to partially desaturate the core sample segments over a number of iterations, referred to as desaturation steps. During each desaturation step, the desaturation device 118 can be used to desaturate the core sample segments. The desaturation device 118 can remove the fluid from each of the core sample segments through centrifugation or desaturation pressure. For example, the desaturation device 118 can exert a force to expel the fluid from porous spaces within each of the core sample segments. In some examples, the desaturation device 118 is a centrifuge, in other examples, the desaturation device 118 is a pressure vessel or pressure chamber. In examples in which the desaturation device 118 is the centrifuge, a fixed centrifuge speed can be used at each duration step. A core sample segment can be placed into the centrifuge and spun at the fixed centrifuge speed to expel the fluid in the core sample 102 to reduce a saturation level of the core sample 102. In examples in which the desaturation device 118 is the pressure vessel, a fixed desaturation pressure can be used at each desaturation step. The core sample segment can be placed into the pressure vessel and a desaturation pressure is applied, which acts on the fluid within the core sample segment to expel the fluids from therewithin (e.g., out of pores) to reduce its saturation level.

In some examples, the centrifuge speed or the desaturation pressure can be selected so that the core sample segment is desaturated at a low Leverett J value at each denaturation step. The Leverett J value can represent a ratio of a capillary pressure to an interfacial tension between immiscible fluids (e.g., water and oil) that is multiplied by a pore size characteristic of a porous medium (e.g., such as the core sample segment). Thus, the Leverett J value is a dimensionless parameter that relates a capillary pressure to other factors such as pore geometry and fluid properties. In some examples, to achieve the low Leverett J value, a model or empirical data can be used to estimate one or more Leverett J values that can be considered “low”, wherein capillary forces are relatively weak compared to other factors that influence fluid behavior. A low Leverett J value can be used so that the desaturation process can proceed gradually over a multiple desaturation steps under conditions where capillary pressure effects can be minimized, which allows for controlled and gradual removal of the fluid from pores of the core sample segments. Parameters of the centrifuge or the desaturation chamber, such as centrifuge speed and desaturation pressure can be set to achieve a desired capillary pressure condition.

In some examples, the tool 104 can include a pressure calculator 146, which can be invoked or used during (e.g., following generation of the saturation profiles 126) and/or after the method. The pressure calculator 146 can be used to compute a capillary pressure for each core sample segment at an inlet of the core sample segment using the following expression:

$${P}_{c} = \frac{1}{2} Δ {ρω}^{2} ( {r}^{2} - {( r - l )}^{2} ) , \qquad ( 2 )$$

wherein P_{c} is the capillary pressure, Δρ is a density difference between displacing a fluid (such as water and brine) and the displaced fluid (typically air or oil within the core sample segment), ω is an angular velocity of the centrifuge or a rotational speed, r is a distance from a center to a location where the capillary pressure is calculated, and l is a length of the core sample segment.

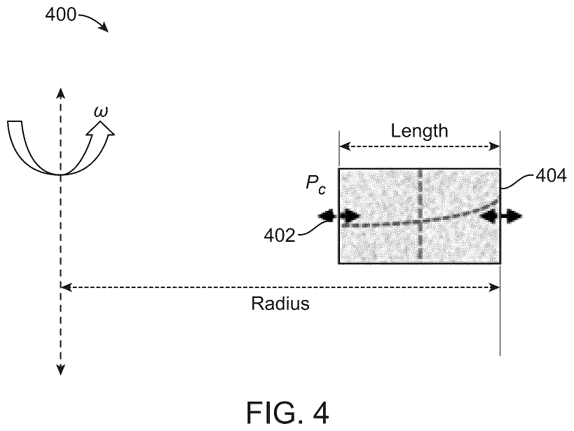

FIG. 4 is an example of a core sample segment 400 at an inlet 402, and reference can be made to one or more examples of FIGS. 1-3 in the example of FIG. 4. The pressure calculator 146 can compute the capillary pressure P_{c} at the inlet 402 based on the radius r of the core sample segment 400, the length l of the core sample segment 400, and the angular velocity ω of the centrifuge, for example, the desaturation device 118.

The inlet 402 of the core sample segment 400 can refer to an end of the core sample segment 400 where the fluid initially enters or where the centrifugal force is applied most during centrifugation. When saturating the core sample segment 400, the inlet 402 is where the saturating fluid first enters the core sample segment 400. This end of the core sample segment 400 can be exposed to the fluid under pressure to ensure complete saturation. During centrifugation, the inlet 402 is the end of the core sample segment facing a direction of the centrifugal force. Such an orientation allows the centrifugal force to push the fluid out from pores of the core sample segment 400.

Continuing with the example of FIG. 1, the pressure calculator 146 can compute capillary pressures for the core sample segments at each desaturation step (e.g., during or after the desaturation step) using expression (2). The pressure calculator 146 can provide capillary pressures data that can indicate a capillary pressure for a respective core sample segment at each desaturation step. In some instances, the capillary pressure computed by the pressure calculator 146 can be referred to as NMR capillary pressure data because the capillary pressure is derived based on NMR measurements, such as the NMR data 116.

In some examples, the tool 104 includes a T2 time cutoff calculator 148 to compute T2 time cutoffs 132 for the core sample segments at different capillary pressure (or each desaturation step). A T2 time cutoff is an identified or specified T2 time threshold that can be used to differentiate between different types of fluids or fluid behaviors within a core sample (or core sample segment). The T2 time cutoff can be used to differentiate between bound water (irreducible water) and free water (movable water) within pore spaces of the core sample segment (or the core sample 102). The T2 time cutoffs 132 can be determined by the T2 time cutoff calculator 148 based on the capillary pressures 130 and the T2 spatial maps 118. For example, as disclosed herein, NMR measurements on the core sample segments at full fluid saturation can be performed to obtain initial T2 time distributions (initial T2 spatial maps). The core sample segments can be partially desaturated at different pressures (or centrifuge speeds) and NMR measurements can be performed after (or at) each desaturation step to obtain additional T2 spatial maps. For each desaturation step, a T2 spatial map for each core sample segment can be evaluated to identify maximum and minimum T2 times. The identified maximum and minimum T2 times can be used by the T2 cutoff calculator 146 with a capillary pressure of the capillary pressures 130 for that core sample segment to compute a corresponding T2 cutoff.

For example, the T2 time cutoff calculator 126 can determine the T2 time cutoff for a core sample segment based on a capillary pressure of the capillary pressures 130 for that core sample segment and minimum and maximum T2 times from the T2 spatial map of the T2 spatial maps 118 for the core sample segment using the following expression:

$${T}_{2 cutoff} = ( {T}_{2 max} - {T}_{2 min} ) {( \frac{{P}_{c}}{{P}_{e}} )}^{λ} + {T}_{2 min} , \qquad ( 2 )$$

wherein T_{2cutoff} represents a T2 time cutoff, T₂ₘₐₓ and T₂ₘᵢₙ represent maximum and minimum T2 times from a T2 spatial map for a given core sample segment, respectively, P_{c} is the capillary pressure, Pₑ is a reference capillary pressure, and A is a fitting parameter.

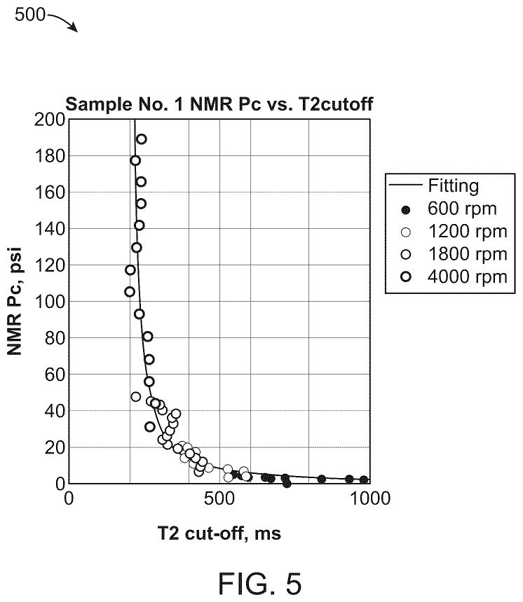

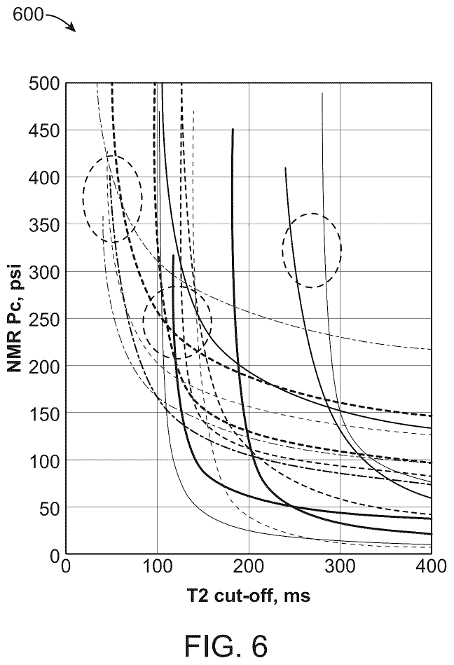

In some examples, the T2 time cutoff calculator 146 can use a power function to fit computed T2 time cutoffs and corresponding capillary pressures of the core sample segment compared at different centrifuge speeds to produce a T2 time cutoff capillary pressure curve. The T2 time cutoff capillary pressure curve can represent capillary pressure changes as a function of T2 time cutoff values for one or more core sample segments at different capillary pressures. FIG. 5 is an example of a graph 500 of a T2 time cutoff capillary pressure curve for a core sample segment. FIG. 6 is an example of a graph 600 of T2 cutoff time capillary pressure curves for the core sample segments. Thus, reference can be made to one or more examples of FIGS. 1-4 in the example of FIGS. 5-6. An x-axis of the graphs 500-600 can represent T2 cutoffs in milliseconds (ms), and a y-axis of the graphs 500-600 can represent a capillary pressure in PSI. For samples with high permeability, the T2 time cutoff capillary pressure curves in each of the graphs 500-600 can show a vertical asymptote at a non-zero water saturation level, indicating that the capillary pressure remains high even as T2 time cutoff values increase. The slope of the fitted curve in examples FIGS. 5-6 can provide an insight into a relationship between T2 time cutoffs and capillary pressures. For example, a steep slope (e.g., a slope of a curve with about a zero rate of change) indicates a rapid change in capillary pressure with small changes in T2 time cutoff values, while a gentle slope (e.g., a curve with gradually decreasing slope) suggests a more gradual change. In the example of FIG. 6, oval circles are used to indicate the vertical approximate parts of the curves (e.g., steep slopes).

Continuing with the example of FIG. 1, the T2 time cutoff capillary pressure curve (or data used in generating the curve), can be analyzed by the T2 time cutoff calculator 146 for each core sample segment to identify T2 time cutoff candidates 134. For example, for each core sample segment, the T2 cutoff calculator 146 can identify a T2 cutoff value where there is a 4% reduction within a 20 psi interval based on the T2 time cutoffs 132 and the capillary pressures 130 for that core segment (or the T2 cutoff capillary pressure curve). The T2 time cutoff candidates 134 can be used as an approximation for irreducible water saturation and desaturation pressure. For example, if the capillary pressure is less than 50 PSI, a T2 time cutoff value at (or associated with the) 50 PSI can be used. If no data points meet the 4% reduction reference, a T2 time cutoff at a maximum capillary pressure can be used.

The T2 time cutoff calculator 146 can use the identified T2 time cutoff candidates 134 and a capillary pressure for each identified T2 time cutoff candidate from the capillary pressures 130 for each of the core sample segments to generate irreducible data points 128. An irreducible data point refers to a combination of a T2 time cutoff value and a corresponding capillary pressure value that represents a point at which irreducible water saturation occurs in a core sample segment. This data point can be used to approximate a condition where fluid is bound within the pore spaces and cannot be removed by capillary forces.

For example, the T2 time cutoff calculator 146 can evaluate the T2 time cutoff capillary pressure curve for the core sample segment to detect that between 50 PSI and 70 PSI that the T2 cutoff decreases from 210 mms to 200 ms. The T2 time cutoff calculator 146 can compute a percentage reduction based on the minimum and maximum T2 time values (e.g., 210 and 200 ms) and compare the percentage reduction to reduction criteria, such as a reduction percentage, for example, 4%. If the percentage reduction satisfies the reduction criteria (e.g., is within a given value or range 4%) can be an indication that the percentage reduction meets a reduction reference criteria. A midpoint T2 time cutoff value and midpoint PSI value, such as 205 ms and 60 PSI can be selected as an approximation of the capillary pressure, and provided as an irreducible data point. Thus, the T2 cutoff calculator 146 generates an irreducible data point using an identified T2 time cutoff candidate and corresponding capillary pressure. An example irreducible data point is: (205 ms, 60 psi).

In some examples, the tool 104 includes a clustering algorithm 150 that has been trained to provide data clusters 152 representing variations in T2 time cutoff values and capillary pressures across core sample segments based on the irreducible data points 128. Each data cluster of the data clusters 152 can represent a group of core sample segments with similar characteristics. In some examples, the clustering algorithm 150 is a dynamic K-means clustering algorithm that has been trained to detect groupings of core sample segments based on corresponding T2 time cutoff values and capillary pressures based on the irreducible data points 128. For example, the clustering algorithm 150 can identify patterns and/or relationships between T2 time cutoff values and capillary pressures to distinguish between core sample segments with different pore structures and fluid distributions. For example, the tool 104 can train the clustering algorithm 150 based on data points consisting of T2 time cutoff values and corresponding capillary pressures, which can be referred to as training data. Each data point represents a specific core sample segment at a given desaturation pressure in the training data. The T2 time cutoff values can be multiplied by a factor larger than one to increase their weight in the distance calculation. This ensures that the T2 time values have a significant impact on the clustering process.

The output of the clustering algorithm 150 can be clusters of core sample segments that share similar properties. For example, a first data cluster of the data clusters 152 can include data points associated with core sample segments 1, 2, and 5, and a second data cluster of the data clusters 152 can include data points associated with core sample segments 3 and 4. An average T2 value can be calculated for each data cluster and used in further calculations to determine a BVI and FFI, respectively for each data cluster of the data clusters 152. BVI is a volume of a liquid (e.g., water) that is irreducibly bound within a rock's pore spaces and cannot be produced. FFI can represent a volume of a fluid that is free to move and can be produced from a reservoir.

The data clusters 152 can be received by a permeability calculator 140. For each data cluster, the permeability calculator 140 can use associated or assigned T2 time cutoff values and capillary pressures values to compute an average T2 time cutoff value and capillary pressure value for the core sample segments associated with that cluster. Using the average T2 time cutoff value for each data cluster, the permeability calculator 140 can separate BVI and FFI for each sample within that data cluster. For example, a first average T2 time cutoff value can be used to identify a first set of T2 time distributions less than the first average T2 time cutoff value and a second set of T2 time distributions above the first average T2 time cutoff value. The permeability calculator 140 can sum a volume for each of the first set of T2 time distributions to provide a BVI value, and a volume for each of the second set of T2 time distributions to provide a FFI value. Each T2 time value of one or more T2 distributions can have an associated amplitude or signal intensity, which can represent a volume of a fluid (typically water) corresponding to that specific T2 time. NMR logging measurements can be used to provide a T2 time distribution corresponding to a T2 spatial map, such as disclosed herein. The T2 time distribution can be a histogram or spectrum (map) that shows the amount of fluid (volume) associated with different T2 times. For example, each bin or point in the T2 time distribution has an associated amplitude or signal intensity. This amplitude represents the relative volume of fluid corresponding to that specific T2 time.

For example, the permeability calculator 140 can use the average T2 time cutoff value to separate T2 time distributions for a data cluster into BVI and FFI components. The permeability calculator 140 can sum volumes (or amplitudes) associated with T2 time distributions that are below and above the average T2 time cutoff value to provide the BVI and FFI value, respectively. Thus, the permeability calculator 140 can determine BVI and FFI values for each of the data clusters 152. The permeability calculator 140 can use expression (1), the Timur-Coats equation, and for each data cluster using corresponding BVI and FFI values to compute fitting parameters C. For example, the permeability calculator 140 can determine a first fitting parameter C based on the BVI and FFI values computed for a first data cluster of the data clusters 152 and a second fitting parameter C based on the BVI and FFI values computed for a second data cluster of the data clusters 152. The permeability calculator 140 can compute an average fitting parameter C based on the first and second fitting parameters C. In some examples, in expression (1), the fitting parameter C can be obtained by the permeability calculator 140 by minimizing a difference of predicted and measured permeability.

The permeability calculator 140 can use the average fitting parameter C and determined porosity to predict a permeability 160 of core sample 102. For example, the permeability 160 can be a spatial permeability distribution of the core sample 102 (and thus the reservoir). The average fitting parameter C can be applied to new core samples to predict the permeability 160 in similar geological formations. This can be used in reservoir characterization and/or evaluation. In some examples, the predicted permeability 160 can be incorporated into reservoir simulation models to understand fluid flow, production forecasting, and/or improve recovery methods.

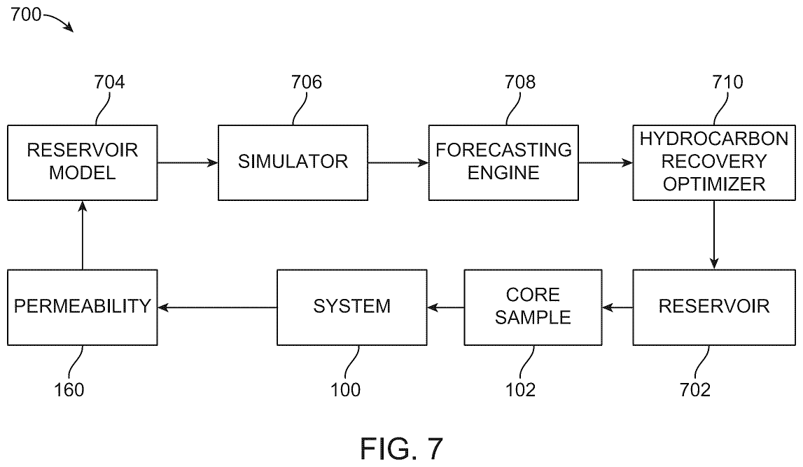

FIG. 7 is an example of a system 700 for hydrocarbon recovery optimization and recovery management 700. The system 700 includes the system 100, as shown in FIG. 1. Thus, reference can be made to one or more examples of FIGS. 1-6 in the example of FIG. 7. One or more core samples 102 can be extracted or retrieved from a reservoir 702 and processed by the system 100 to compute the permeability 160 (permeability distribution). The permeability 160 can be provided to a reservoir model 704. The reservoir model 704 is set up with a geological framework that includes the spatial distribution of rock properties, such as porosity and permeability, within the reservoir 702. The reservoir 702 can be divided into a grid of cells. Each cell represents a small volume of the reservoir rock. The predicted permeability values are assigned to these cells based on the core sample data and the average fitting parameter C. The system 700 includes a simulator 706 to simulate the reservoir model 704 using permeability values (the permeability 160) to calculate how fluids (oil, water, and gas) can flow through each cell. High permeability means fluids can flow more easily, while low permeability means fluid flow is restricted. The simulator 706 solves a series of equations that describe the flow of fluids through porous media. These equations consider the pressure difference, fluid properties, and permeability of the cells to determine the rate and direction of fluid flow. By simulating fluid flow over time, the simulator 706 can predict how much oil, gas, and water will be produced from the reservoir. This helps in forecasting production rates and estimating the total recoverable resources. The system 700 includes a forecasting engine 708 that uses the predictions from the simulator 706 to forecast production rates, and/or estimating total recoverable resources. The system 700 includes a hydrocarbon recovery optimizer 710, which uses the predictions from the forecasting engine 708 to evaluate different recovery methods (e.g., water flooding, gas injection) by simulating their effects on fluid flow and production. This allows engineers to optimize recovery techniques to maximize hydrocarbon extraction. In some examples, the reservoir model 704 can be continuously simulated using updated permeability predictions to allow for improved reservoir management and thus help in making more informed decisions, on well placement, production strategies and enhancing recovery methods. Thus, the system 700 can be used to drive where wells are placed in the reservoir 702. Accordingly, by incorporating the predicted permeability from the tool 104 into the reservoir simulation models, engineers and geologists can better understand the reservoir's behavior, forecast production, and optimize recovery methods, ultimately improving the efficiency and effectiveness of reservoir management.

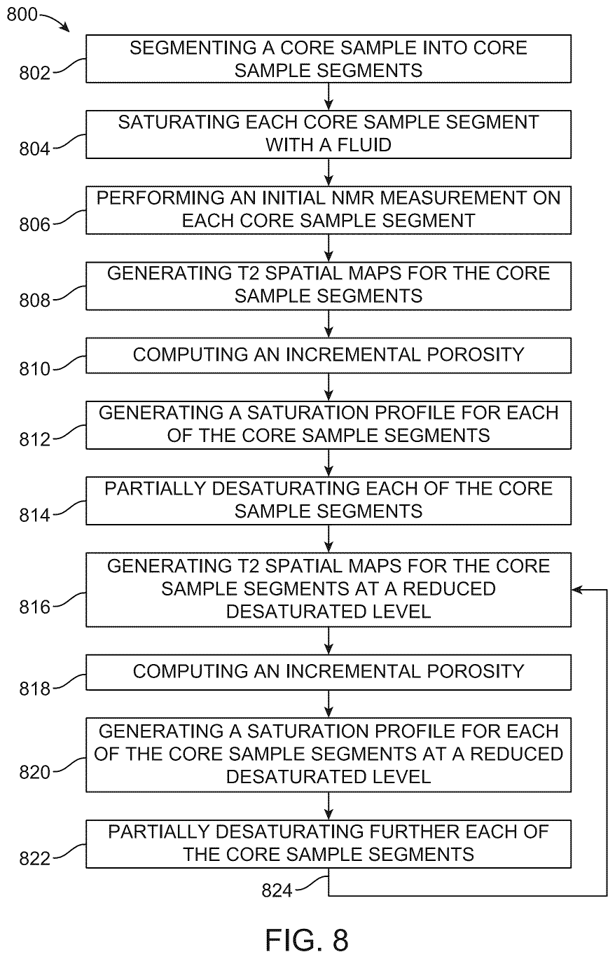

In view of the foregoing structural and functional features described above, example methods will be better appreciated with reference to FIGS. 8-10. While, for purposes of simplicity of explanation, the example methods of FIGS. 7-10 are shown and described as executing serially, it is to be understood and appreciated that the present example is not limited by the illustrated order, as some actions could in other examples occur in different orders, multiple times and/or concurrently from that shown and disclosed herein. Moreover, it is not necessary that all described actions be performed to implement the methods.

FIG. 8 is an example of a method 800 for generating saturation profiles for use in capillary pressure determination. One or more steps of the method 800 can be implemented by the tool 104, as shown in FIG. 1. Thus, reference can be made to one or more examples of FIGS. 1-7 in the example of FIG. 8. The method 800 can begin at 802 with the core sample being segmented into core sample segments (or discrete segments). At 804, each core sample segment is saturated with a fluid (e.g., Brine) to achieve full fluid saturation (e.g., about 100% water saturation). At 806, an initial NMR measurement is performed on each core sample segment using an NMR device to obtain NMR data for each core sample segment. At 808, T2 spatial maps are generated for the core sample segments. At 810, an incremental porosity for each of the core sample segments is computed based on the T2 spatial maps. At 812, a saturation profile for the core sample segments at full fluid saturation is generated based on computed incremental porosity values and segment length values. At 814, each of the fully saturated core sample segments undergo a partial (incremental) desaturation process to partially desaturate the core sample segments over a range or a number of different centrifuge speeds in a same or similar manner as disclosed herein. A 816, following each incremental desaturation, NMR measurements are performed on each core sample segment using the NMR device to obtain NMR data for each core sample segment at a given fluid desaturation level (e.g., 85% water saturation). At 818, T2 spatial maps are generated for the core sample segments at the given fluid desaturation level. At 820, an incremental porosity for each of the core sample segments at the given fluid desaturation level is computed based on the T2 spatial maps. At 822, a saturation profile for the core sample segments is generated based on computed incremental porosity values and segment length values for the core sample segments at the given fluid desaturation level. The method 800 can proceed at 824 back to step 816 for one or more rounds of partial desaturation, which each can be performed at even further reduced fluid saturation level. After each round, NMR measurements are taken, and T2 spatial maps are generated. Each incremental desaturation and subsequent measurement provides additional saturation profiles, characterizing the porosity of the core sample segments at different saturation levels. The series of saturation profiles obtained from fully saturated to various reduced saturation levels are compiled into a comprehensive set of saturation profiles. Each profile characterizes the incremental porosity of the core sample segments across a range of saturation levels.

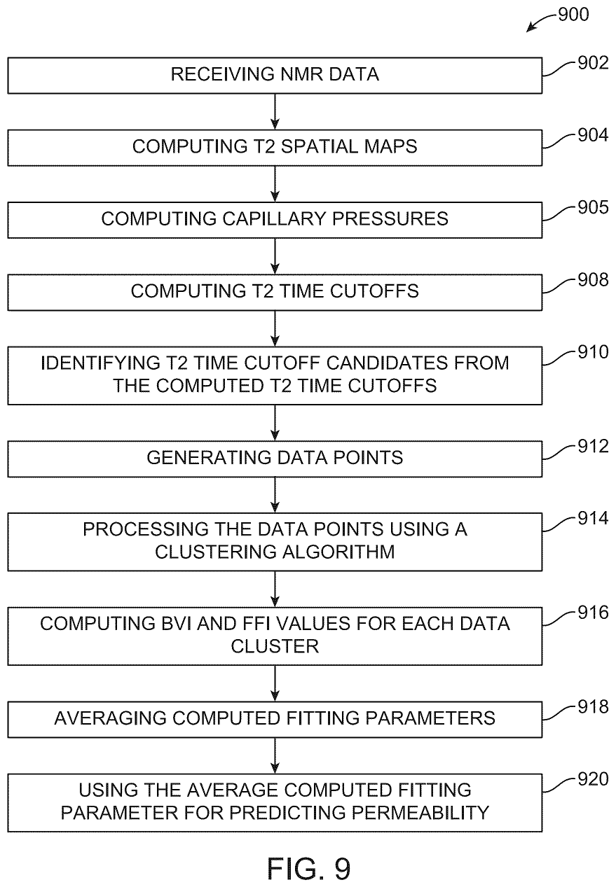

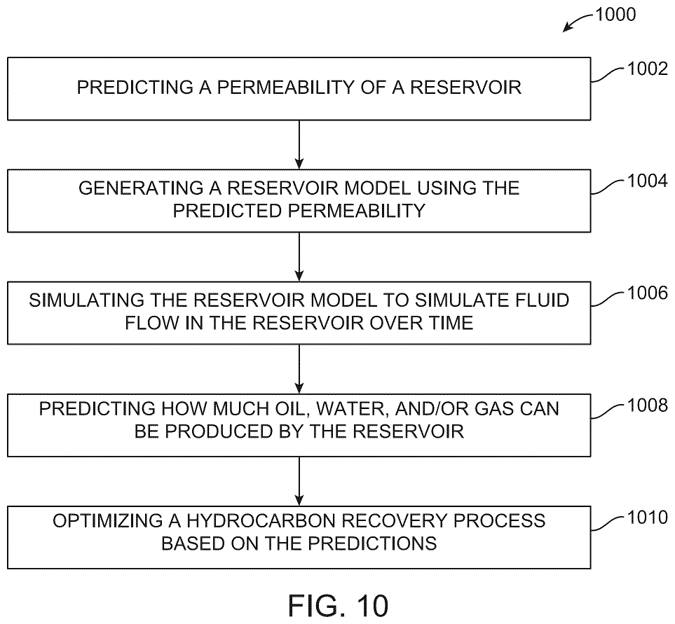

FIG. 9 is an example of a method 900 for predicting a permeability of a rock formation. One or more steps of the method 900 can be implemented by the system 100, as shown in FIG. 1. Thus, reference can be made to one or more examples of FIGS. 1-9 in the example of FIG. 10. The method 900 can begin at 902 by receiving NMR data (e.g., the NMR data 116, as shown in FIG. 1) for one or more core sample segments of a core sample (e.g., the core sample 102, as shown in FIG. 1). At 904, computing T2 spatial maps (e.g., the T2 spatial maps 118, as shown in FIG. 1) for each of the core sample segments based on the NMR data. At 906, computing a capillary pressure at an inlet of each of the one or more core samples to provide capillary pressures (e.g., the capillary pressures 130, as shown in FIG. 1). At 908, computing T2 time cutoffs (e.g., the T2 time cutoffs 132, as shown in FIG. 1) based on the T2 spatial maps. At 910, identifying T2 time cutoff candidates (e.g., the T2 time cutoff candidates 132, as shown in FIG. 1) from the computed T2 time cutoffs. At 912, generating data points (e.g., irreducible data points 128, as shown in FIG. 1) based on the T2 time cutoff candidates and the capillary pressures. Each data point of the data points can include a T2 time cutoff candidate value and capillary pressure value. At 914, processing the data points through a clustering algorithm to group the data points into data clusters (e.g., the data clusters 152, as shown in FIG. 1). At 916, computing BVI and FFI values for each of the data clusters. At 918, fitting parameters for each of the data clusters can be computed based on the computed BVI and FFI values for each of the data clusters. At 918, averaging the computed fitting parameters to generate an average fitting parameter. At 920, using the averaged computed fitting parameter in a permeability prediction model to predict a permeability (e.g., the permeability 160, as shown in FIG. 1) of a reservoir (e.g., the reservoir 702, as shown in FIG. 7).

FIG. 10 is an example of a method 1000 for hydrocarbon recovery optimization. One or more steps of the method 1000 can be implemented by the system, as shown in FIG. 7. Thus, reference can be made to one or more examples of FIGS. 1-9 in the example of FIG. 10. The method 1000 can begin at 1002 by predicting a permeability (e.g., the permeability 160, as shown in FIG. 7) of a reservoir (e.g., the reservoir 702, as shown in FIG. 7). In some examples, the step 1002 can include the method 900, as shown in FIG. 9. At 1004, generating a reservoir model (e.g., the reservoir model 704, as shown in FIG. 7) of the reservoir using the permeability. At 1006, simulating the reservoir model to simulate fluid flow in the reservoir over time. At 1008, predicting based on the simulation how much oil, gas, and/or water can be produced by the reservoir. At 1010, optimizing a hydrocarbon recovery process of hydrocarbons from the reservoir based on the predictions from the simulation.

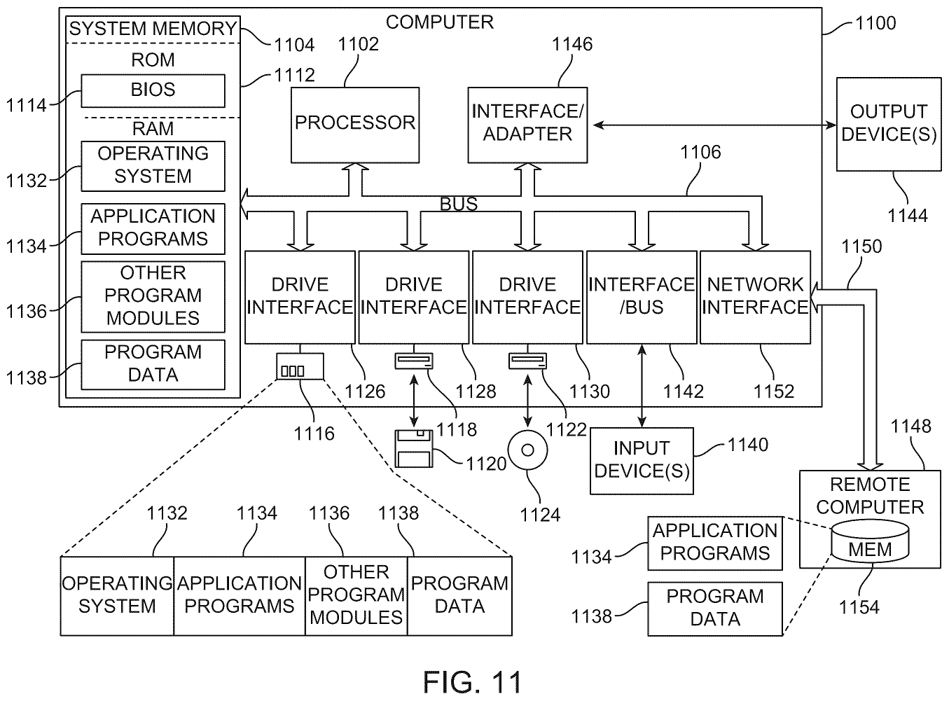

In view of the foregoing structural and functional description, those skilled in the art will appreciate that portions of the embodiments may be embodied as a method, data processing system, or computer program product. Accordingly, these portions of the present embodiments may take the form of an entirely hardware embodiment, an entirely software embodiment, or an embodiment combining software and hardware, such as shown and described with respect to the computer system of FIG. 11. Thus, reference can be made to one or more examples of FIGS. 1-10 in the example of FIG. 1.

In this regard, FIG. 11 illustrates one example of a computer system 1100 that can be employed to execute one or more embodiments of the present disclosure. Computer system 1100 can be implemented on one or more general purpose networked computer systems, embedded computer systems, routers, switches, server devices, client devices, various intermediate devices/nodes, or standalone computer systems. Additionally, computer system 1100 can be implemented on various mobile clients such as, for example, a personal digital assistant (PDA), laptop computer, pager, and the like, provided it includes sufficient processing capabilities.

Computer system 1100 includes processing unit 1102, system memory 1104, and system bus 1106 that couples various system components, including the system memory 1104, to processing unit 1102. Dual microprocessors and other multi-processor architectures also can be used as processing unit 1102. System bus 1106 may be any of several types of bus structure including a memory bus or memory controller, a peripheral bus, and a local bus using any of a variety of bus architectures. System memory 1104 includes read only memory (ROM) 1110 and random access memory (RAM) 1112. A basic input/output system (BIOS) 1114 can reside in ROM 1112 containing the basic routines that help to transfer information among elements within computer system 1100.

Computer system 1100 can include a hard disk drive 1116, magnetic disk drive 1118, e.g., to read from or write to removable disk 1120, and an optical disk drive 1122, e.g., for reading CD-ROM disk 1124 or to read from or write to other optical media. Hard disk drive 1116, magnetic disk drive 1118, and optical disk drive 1122 are connected to system bus 1106 by a hard disk drive interface 1126, a magnetic disk drive interface 1128, and an optical drive interface 1130, respectively. The drives and associated computer-readable media provide nonvolatile storage of data, data structures, and computer-executable instructions for computer system 1100. Although the description of computer-readable media above refers to a hard disk, a removable magnetic disk and a CD, other types of media that are readable by a computer, such as magnetic cassettes, flash memory cards, digital video disks and the like, in a variety of forms, may also be used in the operating environment; further, any such media may contain computer-executable instructions for implementing one or more parts of embodiments shown and disclosed herein. A number of program modules may be stored in drives and RAM 1110, including operating system 1132, one or more application programs 1134, other program modules 1136, and program data 1138. In some examples, the application programs 1134 can include one or more modules (or block diagrams), or systems, as shown and disclosed herein. Thus, in some examples, the application programs 1134 can include the tool 104, as shown in FIG. 1.

A user may enter commands and information into computer system 1100 through one or more input devices 1110, such as a pointing device (e.g., a mouse, touch screen), keyboard, microphone, joystick, game pad, scanner, and the like. These and other input devices are often connected to processing unit 1102 through a corresponding port interface 1122 that is coupled to the system bus, but may be connected by other interfaces, such as a parallel port, serial port, or universal serial bus (USB). One or more output devices 1144 (e.g., display, a monitor, printer, projector, or other type of displaying device) is also connected to system bus 1106 via interface 1146, such as a video adapter.

Computer system 1100 may operate in a networked environment using logical connections to one or more remote computers, such as remote computer 1148. Remote computer 1148 may be a workstation, computer system, router, peer device, or other common network node, and typically includes many or all the elements described relative to computer system 1100. The logical connections, schematically indicated at 1150, can include a local area network (LAN) and a wide area network (WAN). When used in a LAN networking environment, computer system 1100 can be connected to the local network through a network interface or adapter 1152. When used in a WAN networking environment, computer system 1100 can include a modem, or can be connected to a communications server on the LAN. The modem, which may be internal or external, can be connected to system bus 1106 via an appropriate port interface. In a networked environment, application programs 1134 or program data 1138 depicted relative to computer system 1100, or portions thereof, may be stored in a remote memory storage device 1154.

Although this disclosure includes a detailed description on a computing platform and/or computer, implementation of the teachings recited herein are not limited to only such computing platforms. Rather, embodiments of the present disclosure are capable of being implemented in conjunction with any other type of computing environment now known or later developed.

Cloud computing is a model of service delivery for enabling convenient, on-demand network access to a shared pool of configurable computing resources (e.g., networks, network bandwidth, servers, processing, memory, storage, applications, virtual machines, and services) that can be rapidly provisioned and released with minimal management effort or interaction with a provider of the service. This cloud model may include at least five characteristics, at least three service models (e.g., software as a service (Saas, platform as a service (PaaS), and/or infrastructure as a service (IaaS)) and at least four deployment models (e.g., private cloud, community cloud, public cloud, and/or hybrid cloud). A cloud computing environment can be service oriented with a focus on statelessness, low coupling, modularity, and semantic interoperability.

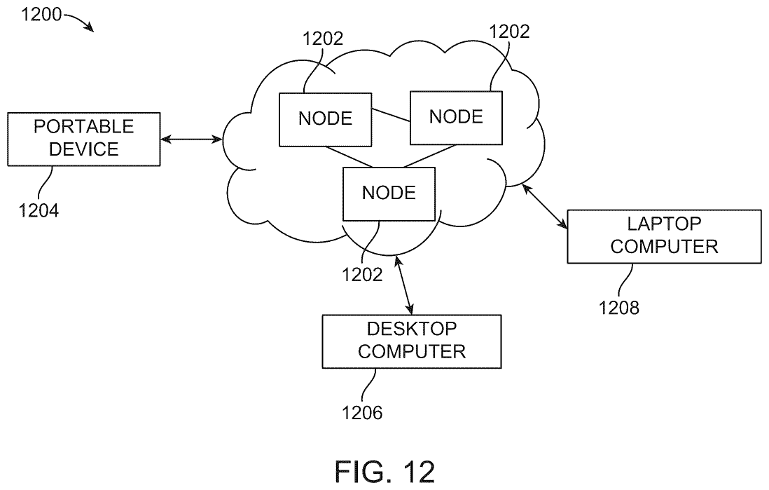

FIG. 12 is an example of a cloud computing environment 1200 that can be used for implementing one or more modules and/or systems in accordance with one or more examples, as disclosed herein. Thus, reference can be made to one or more examples of FIGS. 1-12 in the example of FIG. 12. As shown, cloud computing environment 1200 can include one or more cloud computing nodes 1202 with which local computing devices used by cloud consumers (or users), such as, for example, personal digital assistant (PDA), cellular, or portable device 1204, a desktop computer 1206, and/or a laptop computer 1208, may communicate. The computing nodes 1202 can communicate with one another. In some examples, the computing nodes 1202 can be grouped (not shown) physically or virtually, in one or more networks, such as Private, Community, Public, or Hybrid clouds, or a combination thereof. This allows the cloud computing environment 1200 to offer infrastructure, platforms and/or software as services for which a cloud consumer does not need to maintain resources on a local computing device. The devices 1204-1208, as shown in FIG. 12, are intended to be illustrative and that computing nodes 1202 and cloud computing environment 1200 can communicate with any type of computerized device over any type of network and/or network addressable connection (e.g., using a web browser). In some examples, the one or more computing nodes 1202 are used for implementing one or more examples disclosed herein relating to root-source identification. Thus, in some examples, the one or more computing nodes can be used to implement modules, platforms, and/or systems, as disclosed herein.

In some examples, the cloud computing environment 1200 can provide one or more functional abstraction layers. It is to be understood that the cloud computing environment 1200 need not provide all of the one or more functional abstraction layers (and corresponding functions and/or components), as disclosed herein. For example, the cloud computing environment 1200 can provide a hardware and software layer that can include hardware and software components. Examples of hardware components include mainframes; RISC (Reduced Instruction Set Computer) architecture based servers; servers; blade servers; storage devices; and networks and networking components. In some embodiments, software components include network application server software and database software.

In some examples, the cloud computing environment 1200 can provide a virtualization layer that provides an abstraction layer from which the following examples of virtual entities may be provided: virtual servers; virtual storage; virtual networks, including virtual private networks; virtual applications and operating systems; and virtual clients. In some examples, the cloud computing environment 1200 can provide a management layer that can provide the functions described below. For example, the management layer can provide resource provisioning that can provide dynamic procurement of computing resources and other resources that are utilized to perform tasks within the cloud computing environment. The management layer can also provide metering and pricing to provide cost tracking as resources are utilized within the cloud computing environment 1200, and billing or invoicing for consumption of these resources. In one example, these resources may include application software licenses. Security provides identity verification for cloud consumers and tasks, as well as protection for data and other resources. The management layer can also provide a user portal that provides access to the cloud computing environment 1200 for consumers and system administrators. The management layer can also provide service level management, which can provide cloud computing resource allocation and management such that required service levels are met. Service Level Agreement (SLA) planning and fulfillment can also be provided to provide pre-arrangement for, and procurement of, cloud computing resources for which a future requirement is anticipated in accordance with an SLA.

In some examples, the cloud computing environment 1200 can provide a workloads layer that provides examples of functionality for which the cloud computing environment 1200 may be utilized. Examples of workloads and functions which may be provided from this layer include mapping and navigation; software development and lifecycle management; virtual classroom education delivery; data analytics processing; and transaction processing. Various embodiments of the present disclosure can utilize the cloud computing environment 1200.

The present disclosure is also directed to the following exemplary embodiments, which can be practiced in any combination thereof:

Embodiment A: a method comprising: generating T2 spatial maps for core sample segments of a core sample from a reservoir; computing capillary pressures at an inlet of the core sample segments; computing T2 time cutoffs for the core sample segments based on the T2 spatial maps and the computed capillary pressures; identifying candidate T2 time cutoffs from the computed T2 time cutoffs; generating data points based on the identified candidate T2 time cutoffs and the computed capillary pressures, each data point of the data points comprising a capillary pressure value and a candidate T2 time cutoff value; processing the data points using a clustering algorithm to group the data points into data clusters; and predicting a permeability of the reservoir based on the data clusters.

Embodiment B: A system comprising: a tool comprising: an NMR calculator to generate T2 spatial maps for core sample segments based on T2 times computed for one or more core sample segments of a core sample from a reservoir; a pressure calculator to compute capillary pressures at an inlet of the core sample segments; a T2 time cutoff calculator to: compute T2 time cutoffs for the core sample segments based on the T2 spatial maps and the computed capillary pressures and identify candidate T2 time cutoffs from the computed T2 time cutoffs; generate data points based on the identified candidate T2 time cutoffs and the computed capillary pressures, each data point of the data points comprising a capillary pressure value and a candidate T2 time cutoff value; a clustering algorithm to process the data points to group the data points into data clusters; and a permeability calculator to predict a permeability of the reservoir based on the data clusters.

Embodiment C: a method comprising: providing a reservoir model based on a predicted permeability of a reservoir, the predicted permeability being generated based on data clusters provided by a clustering algorithm based on data points, each data point of the data points comprising a capillary pressure value and a candidate T2 time cutoff value for one or more core sample segments of a core sample from the reservoir; simulating the reservoir model to predict fluid flow in the reservoir; and optimizing a hydrocarbon recovery process of hydrocarbons from the reservoir based on one or more predictions from the simulation of the reservoir model.

Each of embodiment's A through C may have one or more of the following additional elements in any combination: Embodiment 1: wherein the predicting is further based on a permeability prediction model; Embodiment 2: wherein the predicting comprises: computing average T2 time cutoff values for the data clusters; and determining, for each of the data clusters, BVI and FFI values based on the average T2 time cutoff value computed for each data cluster; Embodiment 3: wherein the permeability prediction model comprises a fitting parameter, and the method further comprising: computing a fitting parameter value for each of the data clusters using the permeability prediction model based on the BVI and FFI values computed for each data cluster; and computing a final fitting parameter value based on the fitted parameters computed for each of the data clusters; Embodiment 4: wherein the final fitting parameter value is computed by average the fitting parameters computed for each of the data clusters; Embodiment 5: wherein the permeability prediction model is a Timur-Coats equation; Embodiment 6: further comprising performing nuclear magnetic resonance (NMR) measurements on each of the one or more core sample segments to provide NMR data, the NMR data being used to generate the T2 spatial maps; Embodiment 7: further comprising computing a porosity of the core sample; Embodiment 8: further comprising saturating the core sample and segmenting the core sample into the core segments; Embodiment 9: further comprising saturating the core sample and segmenting the core sample into the core segments; Embodiment 10: further comprising segmenting the core sample into the one or more core segments, wherein each of the one or more core segments has a different core segment length; Embodiment 11: further comprising: generating a reservoir model of the reservoir based on the predicted permeability; and simulating the reservoir model to predict fluid flow in the reservoir; Embodiment 12: further comprising forecasting production rates and/or total recoverable resources of the reservoir based on one or more predictions from the simulation of the reservoir model; Embodiment 13: further comprising optimizing a hydrocarbon recovery process of hydrocarbons from the reservoir based on one or more predictions from the simulation of the reservoir model; Embodiment 14: wherein the permeability calculator is to: compute average T2 time cutoff values for the data clusters; and determine, for each of the data clusters, BVI and FFI values based on the average T2 time cutoff value computed for each data cluster; Embodiment 16: wherein the permeability prediction model comprises a fitting parameter, and the permeability calculator is to: compute a fitting parameter value for each of the data clusters using the permeability prediction model based on the BVI and FFI values computed for each data cluster; and compute a final fitting parameter value based on the fitted parameters computed for each of the data clusters; Embodiment 17: further comprising: a reservoir model comprising the predicted permeability; and a simulator to simulate the reservoir model to predict fluid flow in the reservoir; Embodiment 18: further comprising a forecasting engine to forecast production rates and/or total recoverable resources of the reservoir based on one or more predictions from the simulation of the reservoir model; Embodiment 19: wherein a hydrocarbon recovery process of hydrocarbons from the reservoir is optimized based on one or more predictions from the simulation of the reservoir model.

The present invention may be a system, a method, and/or a computer program product at any possible technical detail level of integration. The computer program product may include a computer readable storage medium (or media) having computer readable program instructions thereon for causing a processor to carry out aspects of the present invention. The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware based systems that perform the specified functions or acts or carry out combinations of special purpose hardware and computer instructions.

The terminology used herein is for the purpose of describing particular embodiments only and is not intended to be limiting of the invention. As used herein, for example, the singular forms “a,” “an,” and “the” are intended to include the plural forms as well, unless the context clearly indicates otherwise. It will be further understood that the terms “contains”, “containing”, “includes”, “including,” “comprises”, and/or “comprising,” and variations thereof, when used in this specification, specify the presence of stated features, integers, steps, operations, elements, and/or components, but do not preclude the presence or addition of one or more other features, integers, steps, operations, elements, components, and/or groups thereof. In addition, the use of ordinal numbers (e.g., first, second, third, etc.) is for distinction and not counting. For example, the use of “third” does not imply there must be a corresponding “first” or “second.” Also, as used herein, the terms “coupled” or “coupled to” or “connected” or “connected to” or “attached” or “attached to” may indicate establishing either a direct or indirect connection, and is not limited to either unless expressly referenced as such. Furthermore, to the extent that the terms “includes,” “has,” “possesses,” and the like are used in the detailed description, claims, appendices, and drawings such terms are intended to be inclusive in a manner similar to the term “comprising” as “comprising” is interpreted when employed as a transitional word in a claim. The term “based on” means “based at least in part on.” The terms “about” and “approximately” can be used to include any numerical value that can vary without changing the basic function of that value. When used with a range, “about” and “approximately” also disclose the range defined by the absolute values of the two endpoints, e.g., “about 2 to about 4” also discloses the range “from 2 to 4.” Generally, the terms “about” and “approximately” may refer to plus or minus 5-10% of the indicated number.

What has been described above includes mere examples of systems, computer program products and computer-implemented methods. It is, of course, not possible to describe every conceivable combination of components, products and/or computer-implemented methods for purposes of describing this disclosure, but one of ordinary skill in the art can recognize that many further combinations and permutations of this disclosure are possible. The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

The invention claimed is:

1. A method comprising:
generating relaxation times (T2) spatial maps for core sample segments of a core sample from a reservoir;
computing capillary pressures at an inlet of the core sample segments;
computing T2 time cutoffs for the core sample segments based on the T2 spatial maps and the computed capillary pressures;
identifying candidate T2 time cutoffs from the computed T2 time cutoffs;
generating data points based on the identified candidate T2 time cutoffs and the computed capillary pressures, each data point of the data points comprising a capillary pressure value and a candidate T2 time cutoff value;
processing the data points using a clustering algorithm to group the data points into data clusters; and
predicting a permeability of the reservoir based on the data clusters.

2. The method of claim 1, wherein the predicting is further based on a permeability prediction model.

3. The method of claim 2, wherein the predicting comprises:
computing average T2 time cutoff values for the data clusters; and
determining, for each of the data clusters, bulk volume irreducible (BVI) and free fluid index (FFI) values based on the average T2 time cutoff value computed for each data cluster.

4. The method of claim 3, wherein the permeability prediction model comprises a fitting parameter, and the method further comprising:
computing a fitting parameter value for each of the data clusters using the permeability prediction model based on the BVI and FFI values computed for each data cluster; and
computing a final fitting parameter value based on the fitted parameters computed for each of the data clusters.

5. The method of claim 4, wherein the final fitting parameter value is computed by average the fitting parameters computed for each of the data clusters.

6. The method of claim 2, wherein the permeability prediction model is a Timur-Coats equation.

7. The method of claim 1, further comprising performing nuclear magnetic resonance (NMR) measurements on each of the one or more core sample segments to provide NMR data, the NMR data being used to generate the T2 spatial maps.

8. The method of claim 1, further comprising computing a porosity of the core sample.

9. The method of claim 1, further comprising saturating the core sample and segmenting the core sample into the core segments.

10. The method of claim 1, further comprising segmenting the core sample into the one or more core segments, wherein each of the one or more core segments has a different core segment length.

11. The method of claim 1, further comprising:
generating a reservoir model of the reservoir based on the predicted permeability; and
simulating the reservoir model to predict fluid flow in the reservoir.

12. The method of claim 11, further comprising forecasting production rates and/or total recoverable resources of the reservoir based on one or more predictions from the simulation of the reservoir model.

13. The method of claim 11, further comprising optimizing a hydrocarbon recovery process of hydrocarbons from the reservoir based on one or more predictions from the simulation of the reservoir model.

14. A system comprising:
A tool comprising:
a nuclear magnetic resonance (NMR) calculator to generate relaxation times (T2) spatial maps for core sample segments based on T2 times computed for one or more core sample segments of a core sample from a reservoir;
a pressure calculator to compute capillary pressures at an inlet of the core sample segments;
a T2 time cutoff calculator to:
compute T2 time cutoffs for the core sample segments based on the T2 spatial maps and the computed capillary pressures and identify candidate T2 time cutoffs from the computed T2 time cutoffs;
generate data points based on the identified candidate T2 time cutoffs and the computed capillary pressures, each data point of the data points comprising a capillary pressure value and a candidate T2 time cutoff value;
a clustering algorithm to process the data points to group the data points into data clusters; and
a permeability calculator to predict a permeability of the reservoir based on the data clusters.

15. The system of claim 14, wherein the permeability calculator is to:
compute average T2 time cutoff values for the data clusters; and
determine, for each of the data clusters, bulk volume irreducible (BVI) and free fluid index (FFI) values based on the average T2 time cutoff value computed for each data cluster.

16. The system of claim 15, wherein the permeability prediction model comprises a fitting parameter, and the permeability calculator is to:
compute a fitting parameter value for each of the data clusters using the permeability prediction model based on the BVI and FFI values computed for each data cluster; and
compute a final fitting parameter value based on the fitted parameters computed for each of the data clusters.

17. The system of claim 16, further comprising:
a reservoir model comprising the predicted permeability; and
a simulator to simulate the reservoir model to predict fluid flow in the reservoir.

18. The system of claim 17, further comprising a forecasting engine to forecast production rates and/or total recoverable resources of the reservoir based on one or more predictions from the simulation of the reservoir model.

19. The system of claim 17, wherein a hydrocarbon recovery process of hydrocarbons from the reservoir is optimized based on one or more predictions from the simulation of the reservoir model.

20. A method comprising:
providing a reservoir model based on a predicted permeability of a reservoir, the predicted permeability being generated based on data clusters provided by a clustering algorithm based on data points, each data point of the data points comprising a capillary pressure value and a candidate T2 time cutoff value for one or more core sample segments of a core sample from the reservoir;
simulating the reservoir model to predict fluid flow in the reservoir; and
optimizing a hydrocarbon recovery process of hydrocarbons from the reservoir based on one or more predictions from the simulation of the reservoir model.
